(19) United States
(12) Patent Application Publication
(10) Pub. No.: US 2010/0290200 A1
(43) Pub. Date: Nov. 18, 2010

(54) ELECTRONIC DEVICE

(75) Inventors: Nobuhiro YAMAMOTO, Fussa-shi (JP); Minoru TAKIZAWA, Sagamihara-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/631,717

(22) Filed: Dec. 4, 2009

(30) Foreign Application Priority Data
May 15, 2009 (JP) 2009-118619

(51) Int. Cl. H05K 5/00

(52) U.S. Cl. 361/752

(57) ABSTRACT

According to one embodiment, an electronic device is provided with a conductive member, a printed wiring board including an insulating base member, and a metal foil member provided on one surface of the base member, a fixing member which fixes the printed wiring board to the conductive member, and a conductive adhesive member which covers a surface of the metal foil member and electrically connects the metal foil member to the fixing member.

### CROSS-REFERENCE TO RELATED APPLICATIONS

This application is based upon and claims the benefit of priority from Japanese Patent Application No. 2009-118619, filed May 15, 2009, the entire contents of which are incorporated herein by reference.

### BACKGROUND

1. Field

One embodiment of the present invention relates to an electronic device using a conductive adhesive.

2. Description of the Related Art

Jpn. Pat. Appln. KOKAI Publication No. 2007-311063 discloses a connector coupling structure using a conductive adhesive. The connector coupling structure comprises a connector, a relay circuit board with a relay wiring layer, a membrane circuit board with a printed circuit wiring layer, and a conductive adhesive for electrically connecting the relay wiring layer to the printed circuit wiring layer.

In the connector coupling structure, the membrane circuit board is electrically connected to the relay circuit board without solder. Therefore, even when the membrane circuit board has a low heatproof temperature, it can be used for the connector coupling structure. Since thus, a relatively cheap membrane circuit board can be used, the cost for the entire electric equipment can be reduced.

When copper wiring provided on the above-mentioned general circuit board is exposed to air, copper oxide is formed on the copper wiring. Since the copper oxide will easily peel off, it may well be a factor of dust in an electronic device. To prevent occurrence of dust due to the copper oxide, the copper wiring is often coated with, for example, gold. However, gold plating is expensive and needs a plating process using an agent. The agent drain must be processed separately and discarded after it is used, which requires high environmental cost. Therefore, there is a demand for means used in place of gold plating.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view illustrating a hard disk drive according to a first embodiment;

FIG. 2 is an exemplary exploded perspective view illustrating the hard disk drive of FIG. 1;

FIG. 3 is an exemplary top view illustrating a state in which the first case of the housing of the hard disk drive is detached;

FIG. 4 is an exemplary sectional view illustrating a state in which a flexible printed wiring board contained in the housing of the hard disk drive is expanded;

FIG. 5 is an exemplary enlarged top view illustrating the structure of the portion of the flexible printed wiring board of FIG. 4 that includes a fixing member and a peripheral portion thereof;

FIG. 6 is an exemplary longitudinal sectional view illustrating the portion, shown in FIG. 5, which includes the fixing member and its peripheral portion;

FIG. 7 is an exemplary enlarged top view illustrating the structure of a portion of a flexible printed wiring board in a hard disk drive according to a second embodiment, which portion includes a fixing member and a peripheral portion thereof;

FIG. 8 is an exemplary longitudinal sectional view illustrating the portion, shown in FIG. 7, which includes the fixing member and its peripheral portion;

FIG. 9 is an exemplary enlarged top view illustrating the structure of a portion of a flexible printed wiring board in a hard disk drive according to a third embodiment, which portion includes a fixing member and a peripheral portion thereof;

FIG. 10 is an exemplary enlarged top view illustrating the structure of a portion of a flexible printed wiring board in a hard disk drive according to a fourth embodiment, which portion includes a fixing member and a peripheral portion thereof;

FIG. 11 is an exemplary enlarged top view illustrating the structure of a portion of a flexible printed wiring board in a hard disk drive according to a fifth embodiment, which portion includes a fixing member and a peripheral portion thereof;

FIG. 12 is an exemplary enlarged top view illustrating the structure of a portion of a flexible printed wiring board in a hard disk drive according to a sixth embodiment, which portion includes a fixing member and a peripheral portion thereof;

FIG. 13 is an exemplary enlarged top view illustrating the structure of a portion of a flexible printed wiring board in a hard disk drive according to a seventh embodiment, which portion includes a fixing member and a peripheral portion thereof;

FIG. 14 is an exemplary enlarged top view illustrating the structure of a portion of a flexible printed wiring board according to a modification of the seventh embodiment, which portion includes a fixing member and a peripheral portion thereof;

FIG. 15 is an exemplary enlarged top view illustrating the structure of a portion of a flexible printed wiring board in a hard disk drive according to an eighth embodiment, which portion includes a conductive adhesive and a peripheral portion thereof;

FIG. 16 is an exemplary longitudinal sectional view illustrating the portion, shown in FIG. 15, which includes the conductive adhesive and its peripheral portion;

FIG. 17 is an exemplary perspective view illustrating a portable computer according to a ninth embodiment;

FIG. 18 is an exemplary horizontal sectional view illustrating the main unit of the portable computer shown in FIG. 17; and

FIG. 19 is an exemplary enlarged sectional view illustrating the structure of a portion of a printed wiring board in the main unit shown in FIG. 18, which portion includes a fixing member and a peripheral portion thereof.

### DETAILED DESCRIPTION

Various embodiments according to the invention will be described hereinafter with reference to the accompanying drawings. In general, according to one embodiment of the invention, an electronic device is provided with a conductive member; a printed wiring board including an insulating base member, and a metal foil member provided on one surface of the base member; a fixing member which fixes the printed wiring board to the conductive member; and a conductive adhesive member which covers a surface of the metal foil member and electrically connects the metal foil member to the fixing member.

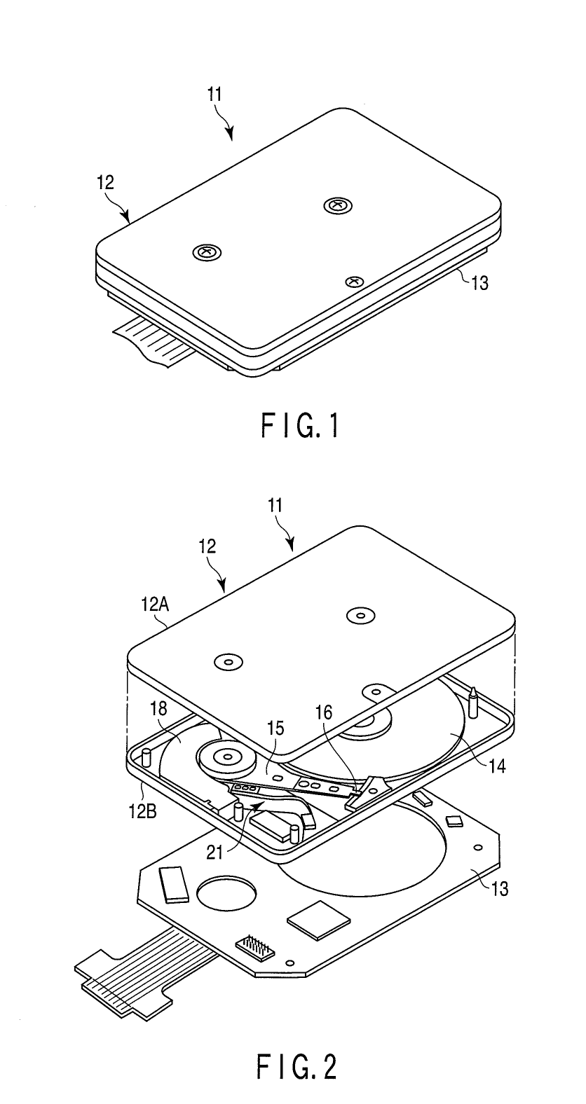

A hard disk drive as an electronic device according to a first embodiment will be described with reference to FIGS. 1 to 6.

As shown in FIGS. 1 to 3, a hard disk drive 11 comprises a metal housing 12, a printed circuit board 13 fixed to an outer surface of the housing 12, a magnetic disk 14 (hard disk) housed in the housing 12, a disk motor for spinning the magnetic disk 14, a rod-shaped carriage 15 rotatably attached to a second case 12B, described later, incorporated in the housing 12, and a recording/reproducing head 16 attached to the tip of the carriage 15.

The housing 12 is a conductive member, and includes an upper (first) case 12A and a lower (second) case 12B. The carriage 15 is formed of a metal, and is another conductive member. The carriage 15 can rotate about a spindle 17 on the second case 12B in a direction parallel to the surface of the magnetic disk 14.

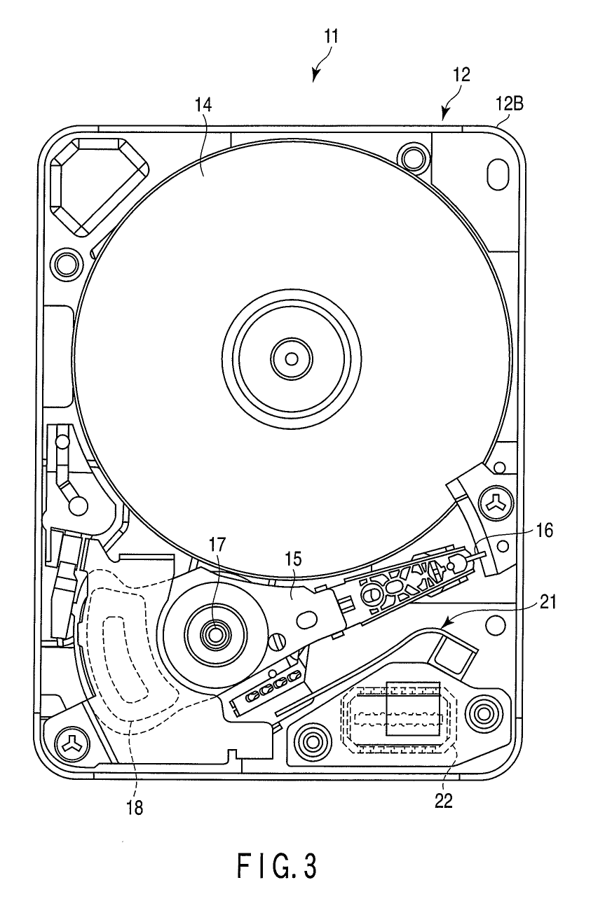

As shown in FIGS. 3 and 5, the hard disk drive 11 further comprises a voice coil motor 18 provided at the base of the carriage 15 for rotating the same, a flexible printed wiring board 21 as an example of a printed wiring board attached to the inner surface of the second case 12B, a support member 22 provided as a conductive member on the reverse surface of the flexible printed wiring board 21, fixing members 23 fixing the flexible printed wiring board 21 to the carriage 15 and the support member 22, and conductive adhesive members 24 covering the entire exposed portions (head portions) 29 of the fixing members 23. The support member 22 is formed of, for example, a stainless thin plate, and is fixed to the second case 12B of the housing 12. In the first embodiment, a screw is used as an example of each fixing member 23.

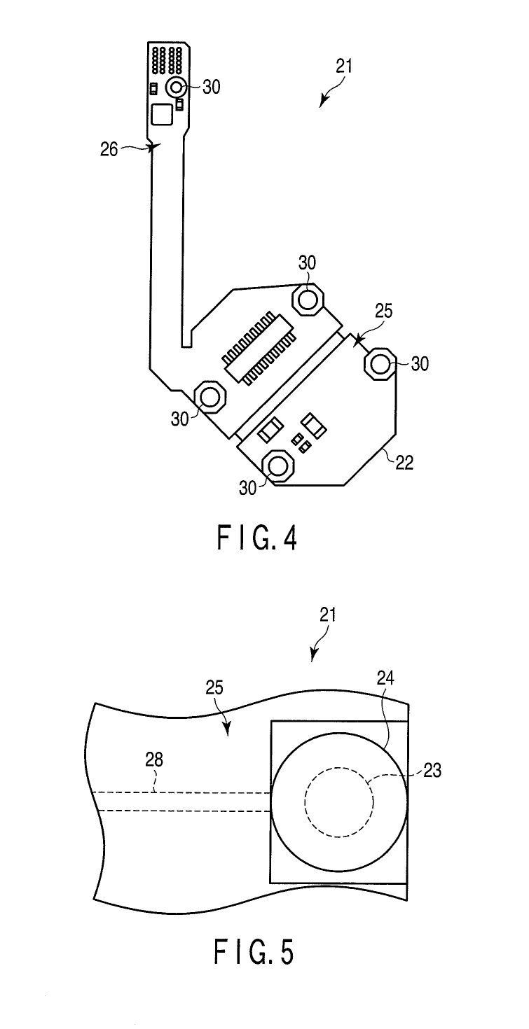

As shown in FIG. 4, the flexible printed wiring board 21 includes a main body 25 folded and fixed to the second case 12B, and an end portion 26 extending like a strip from the main body 25 and serving as a connection connected to the carriage 15. The flexible printed wiring board 21 has holes 30 for inserting the fixing members 23. The flexible printed wiring board 21 is connected to the recording/reproducing head 16 and the voice coil motor 18 via the end portion 26.

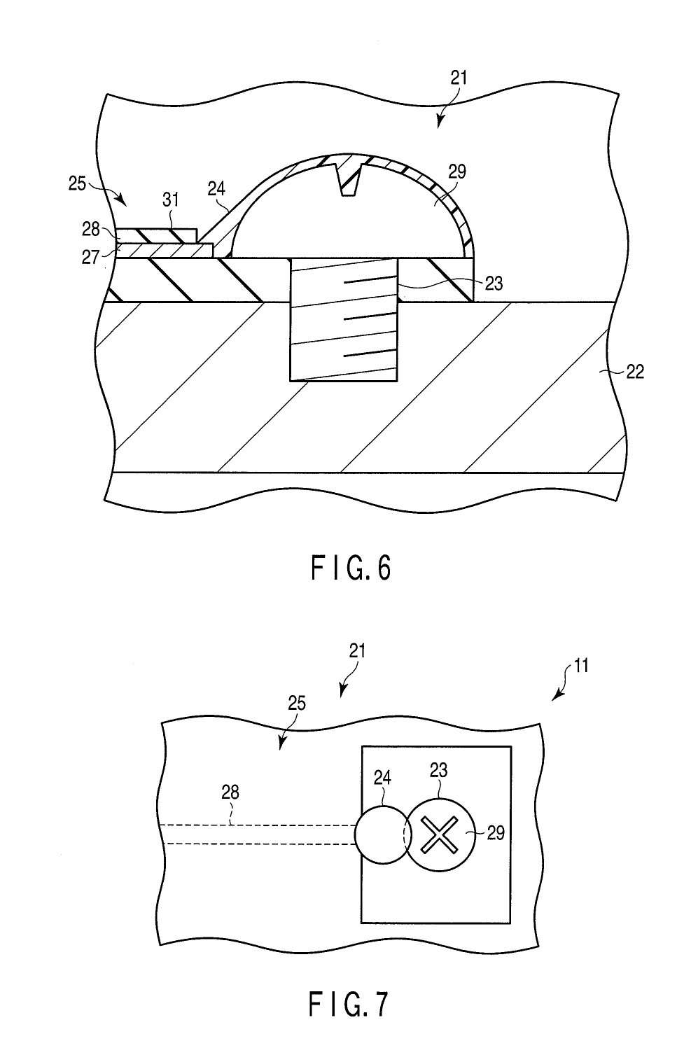

FIGS. 5 and 6 are enlarged views illustrating one of the fixing members 23 and the corresponding conductive adhesive member 24 on the flexible printed wiring board 21. As can be seen from FIG. 6, the flexible printed wiring board 21 comprises an insulating base member 27 formed of, for example, polyimide, metal foil members 28 (copper foil members) provided on one surface of the base member 27, and cover layers 31 formed of, for example, polyimide and covering the metal foil members 28.

The conductive adhesive members 24 are formed of an adhesive that contains, for example, silver particles as conductive particles. Each conductive adhesive member 24 covers the tip of the corresponding metal foil member 28 that is not covered with the corresponding cover layer 31. The conductive particles are not limited to silver particles. The conductive adhesive members 24 electrically connect the metal foil member 28 to the fixing member 23. Before each conductive adhesive member 24 is hardened, no current flows therethrough since the distance between adjacent conductive particles is long. After each conductive adhesive member 24 is hardened, the conductive particles contact each other and collectively function as a conductor.

The main body 25 of the flexible printed wiring board 21 is fixed to the support member 22 as a conductive member at four positions via the fixing members 23. The metal foil members 28 of the main body 25 are grounded to the support member 22 via the corresponding conductive adhesive members 24 and the corresponding fixing members 23. Further, the end portion 26 of the flexible printed wiring board 21 is fixed via the corresponding fixing member 23 to the carriage 15 as another conductive member. The metal foil member 28 of the end portion 26 is grounded to the carriage 15 via the corresponding conductive adhesive member 24 and the corresponding fixing member 23.

In the first embodiment, the hard disk drive 11 comprises: the conductive members; the printed wiring board including the insulating base member 27 and the metal foil members 28 provided on one surface of the base member 27; the fixing members 23 fixing the printed wiring board to the conductive members; and the conductive adhesive members 24 covering surface potions of the metal foil members 28 to electrically connect the metal foil members 28 to the fixing members 23.

Since the surface potions of the metal foil members 28 are thus covered with the conductive adhesive members 24, oxide films that may become dust are prevented from being formed on the metal foil members 28. Further, since gold plating is not used, both the manufacturing cost and the environmental load can be reduced.

Yet further, since the conductive adhesive members 24 electrically connect the metal foil members 28 to the fixing members 23, the metal foil members 28 can reliably be grounded to the conductive members. It is extremely important to ground the printed wiring board to the conductive members and so set the potential of the former to zero, since unnecessary electromagnetic radiation from the printed wiring board can be suppressed. In addition, the conductive adhesive members 24 each interposed between the corresponding metal foil member 28 and the corresponding fixing member 23 enhance the connection strength of the fixing members 23 and their peripheral portions.

Furthermore, since the conductive adhesive members 24 cover the entire exposed portions 29 of the fixing members 23, the connection strength of the fixing members 23 and their peripheral portions is further enhanced, and the fixing members 23 are prevented from being loosened.

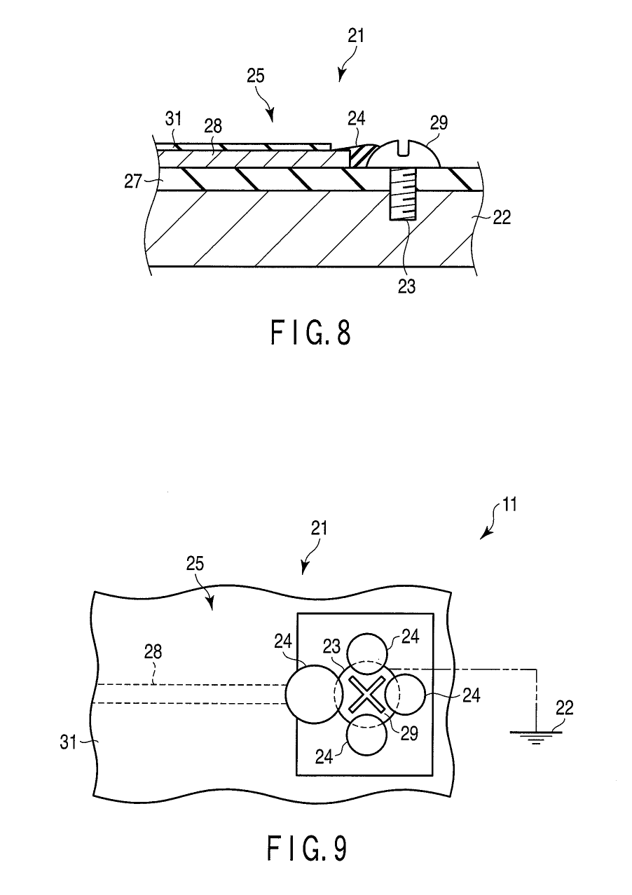

Referring now to FIGS. 7 and 8, an electronic device according to a second embodiment will be described. A hard disk drive 11 as an example of the electronic device of the second embodiment is similar to that of the first embodiment except for the portions covered with the conductive adhesive members 24. In the second embodiment, elements similar to those of the first embodiment are denoted by corresponding reference numbers, and will not be described. A description will be mainly given of different elements. The hard disk drive 11 of the second embodiment has the same appearance as that of FIG. 1.

As shown in FIGS. 7 and 8, each conductive adhesive member 24 covers a part of the exposed portion 29 of the corresponding fixing member 23, and also covers the tip of the corresponding metal foil member 28, thereby electrically connecting the metal foil members 28 to the fixing members 23. The fixing members 23 are kept in contact with a support member 22 as a conductive member. Accordingly, the metal foil members 28 of the main body 25 of the flexible printed wiring board 21 are grounded to the support member 22 via the corresponding conductive adhesive members 24 and the corresponding fixing members 23. Further, the metal foil member 28 of the end portion 26 of the flexible printed wiring board 21 is grounded to the carriage 15 as another conductive member via the corresponding conductive adhesive member 24 and the corresponding fixing member 23 (this structure is not shown in the figures). In the second embodiment, screws, for example, are used as the fixing members 23.

In the second embodiment, each conductive adhesive member 24 covers a part of the exposed portion 29 of the corresponding fixing member 23, and also covers the tip of the corresponding metal foil member 28. This structure prevents dust from occurring from the surfaces of the metal foil members 28. Note that the fixing members 23 themselves are mostly formed of stainless steel, and hence rust will not occur on the fixing members 23 even if the entire exposed portions 29 of the fixing members 23 are not covered.

Further, in the second embodiment, the conductive adhesive members 24 enhance the connection strength of the fixing members 23 and their peripheral portions, and prevent the fixing members 23 from being loosened. Furthermore, the required amount of conductive adhesive can be reduced compared to the first embodiment. Although the conductive adhesive is cheaper than gold, if a great amount of adhesive is used, it costs not too little since the adhesive contains conductive particles such as silver particles. In light of this, the second embodiment uses a smaller amount of conductive adhesive than the first embodiment, thereby reducing the manufacturing cost of the entire electronic device. In addition, since not the entire exposed portions 29 of the fixing members 23 are covered, the fixing members 23 can be detached for, for example, repair. Thus, the maintenance of the electronic device of the second embodiment is easier than that of the first embodiment.

Referring then to FIG. 9, an electronic device according to a third embodiment will be described. A hard disk drive 11 as an example of the electronic device of the third embodiment is similar to that of the second embodiment except for the number of portions covered with the conductive adhesive members 24. In the third embodiment, elements similar to those of the second embodiment are denoted by corresponding reference numbers, and will not be described. A description will be mainly given of different elements. The hard disk drive 11 of the third embodiment has the same appearance as that of FIG. 1.

As shown in FIG. 9, in the hard disk drive 11 of the third embodiment, conductive adhesive members 24 are provided at, for example, four radial positions around the exposed portion 29 of a fixing member 23. However, the number of positions at which the conductive adhesive members 24 are provided is not limited to four, but may be two or three, or five or more. One of the four conductive adhesive members 24 covers the tip of the metal foil member 28 corresponding to the fixing member 23. The four conductive adhesive members 24 cover respective parts of the exposed portion 29 of the fixing member 23. The metal foil members 28 of the main body 25 are grounded to the support member 22 as a conductive member via the corresponding conductive adhesive members 24 and the corresponding fixing members 23. Similarly, the metal foil member 28 of the end portion 26 of the flexible printed wiring board 21 is grounded to the carriage 15 as another conductive member via the corresponding conductive adhesive member 24 and the corresponding fixing member 23.

In the third embodiment, a plurality of conductive adhesive members 24 are provided at a plurality of radial positions around the exposed portion 29 of each fixing member 23. By changing the number of the conductive adhesive members 24 provided around each fixing member 23, the connection strength of each fixing member 23 and the peripheral portion thereof can be easily adjusted in accordance with the conditions and/or portion for which each fixing member is used. Specifically, in a certain portion that requires strong connection, the number of the conductive adhesive members 24 is increased, whereas in another portion that does not require strong connection, the number of the conductive adhesive members 24 is reduced. Further, even after soldering is performed on the flexible printed wiring board 21, or the fixing members 23 are fixed, the connection strength can be freely changed by changing the number of the conductive adhesive members 24.

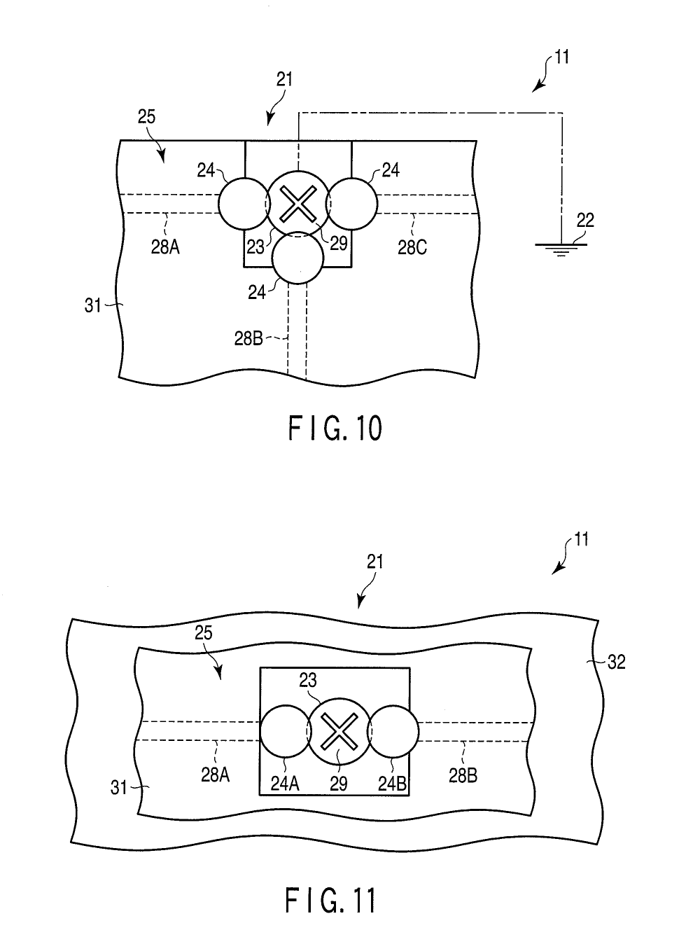

Referring then to FIG. 10, an electronic device according to a fourth embodiment will be described. A hard disk drive 11 as an example of the electronic device of the fourth embodiment is similar to that of the third embodiment except for the numbers of the conductive adhesive members 24 and the metal foil members 28. In the fourth embodiment, elements similar to those of the third embodiment are denoted by corresponding reference numbers, and will not be described. A description will be mainly given of different elements. The hard disk drive 11 of the fourth embodiment has the same appearance as that of FIG. 1.

In the fourth embodiment, the flexible printed wiring board 21 comprises a base member 27, first to third metal foil members 28A to 28C (copper foil members) provided on one surface of the base member 27, and cover layers 31 covering the first to third metal foil members 28A to 28C. The first to third metal foil members 28A to 28C are provided, for example, radially, around each fixing member 23 in the main unit 25 of the flexible printed wiring board 21. Similar first to third metal foil members 28A to 28C are provided, for example, radially, around the fixing member 23 of the end portion 26 of the flexible printed wiring board 21, although this structure is not shown.

The conductive adhesive members 24 are provided at, for example, three positions around the exposed portion (head portion) 29 of a fixing member 23. The three positions of the conductive adhesive members 24 correspond to the first to third metal foil members 28A to 28C. The conductive adhesive members 24 cover respective portions of the exposed portion 29 of the fixing member 23. Further, the conductive adhesive members 24 cover the tips of the first to third metal foil members 28A to 28C that are not covered with the cover layers 31.

The fixing members 23 in the main body 25 of the flexible printed wiring board 21 are connected to a support member 22 as a conductive member. The first to third metal foil members 28A to 28C of the main body 25 are grounded to the support member 22 via the corresponding conductive adhesive members 24 and the corresponding fixing members 23. Similarly, the fixing member 23 of the end portion 26 of the flexible printed wiring board 21 is connected to a carriage 15 as another conductive member. The first to third metal foil members 28A to 28C of the end portion 26 are grounded to the carriage 15 via the corresponding fixing member 23 and the corresponding conductive adhesive members 24.

In the fourth embodiment, a plurality of metal foil members 28 are provided around a fixing member 23, and a plurality of conductive adhesive members 24 correspond to the respective metal foil members 28. Thus, in this structure, the metal foil members 28 are grounded to a conductive member by a single fixing member 23. Namely, this structure is simpler than the structure in which the metal foil members 28 are grounded by respective fixing members.

Referring now to FIG. 11, an electronic device according to a fifth embodiment will be described. A hard disk drive 11 as an example of the electronic device of the fifth embodiment is similar to that of the fourth embodiment except for the number of the conductive adhesive members 24, the number of the metal foil members 28 and the position at which the fixing member 23 is fixed. In the fifth embodiment, elements similar to those of the fourth embodiment are denoted by corresponding reference numbers, and will not be described. A description will be mainly given of different elements. The hard disk drive 11 of the fifth embodiment has the same appearance as that of FIG. 1.

The hard disk drive 11 of the fifth embodiment comprises a metal housing 12, a printed circuit board 13 fixed to an outer surface of the housing 12, a magnetic disk 14 (hard disk) housed in the housing 12, a disk motor for spinning the magnetic disk 14, a rod-shaped carriage 15 rotatably attached to the housing 12, and a recording/reproducing head 16 attached to the tip of the carriage 15. The hard disk drive 11 further comprises a voice coil motor 18 provided at the base of the carriage 15 for rotating the same, a flexible printed wiring board 21 housed in the housing 12, an insulating fixing section 32 provided on the second case 12B of the housing 12, fixing members 23 fixing the flexible printed wiring board 21 to the fixing section 32, and conductive adhesive members 24 covering parts of the exposed portions (head portions) 29 of the fixing members 23.

The flexible printed wiring board 21 includes a base member 27, first metal foil members 28A and second metal foil members 28B (copper foil members) provided on one surface of the base member 27, and cover layers 31 covering the first and second metal foil members 28A and 28B. Each pair of first and second metal foil members 28A and 28B are linearly provided on the main body 25 of the flexible printed wiring board 21, with the corresponding fixing member 23 interposed therebetween. Similar first and second metal foil members 28A and 28B are linearly provided in the end portion 26 of the flexible printed wiring board 21 with the corresponding fixing member 23 interposed therebetween, although this structure is not shown.

The conductive adhesive members 24 cover the tips of the first and second metal foil members 28A and 28B that are not covered with the cover layers 31.

Further, in the fifth embodiment, the conductive adhesive members 24 include first conductive adhesive members 24A corresponding to the first metal foil members 28A, and second conductive adhesive members 24B corresponding to the second metal foil members 28B. Each first conductive adhesive member 24A electrically connects the corresponding first metal foil member 28A to the corresponding fixing member 23, and each second conductive adhesive member 24B electrically connects the corresponding second metal foil member 28B to the corresponding fixing member 23.

In the fifth embodiment, each pair of first and second metal foil members 28A and 28B are electrically connected to each other via the corresponding fixing member 23, and the corresponding first and second conductive adhesive members 24A and 24B, whereby one electric circuit is formed on the flexible printed wiring board 21.

The hard disk drive 11 of the fifth embodiment comprises the flexible printed wiring board 21 including the insulating base member 27, and the first and second metal foil members 28A and 28B provided on one surface of the base member 27, the fixing section 32 to which the flexible printed wiring board 21 is fixed, the fixing members 23 fixing the flexible printed wiring board 21 to the fixing section 32, the first conductive adhesive members 24A covering the surfaces of the first metal foil members 28A to electrically connect the first metal foil members 28A to the fixing members 23, and the second conductive adhesive members 24B covering the surfaces of the second metal foil members 28B to electrically connect the second metal foil members 28B to the fixing members 23.

Since in this structure, each pair of first and second conductive adhesive members 24A and 24B and the corresponding fixing member 23 provide one electric circuit, they can be used as part of the electric circuit.

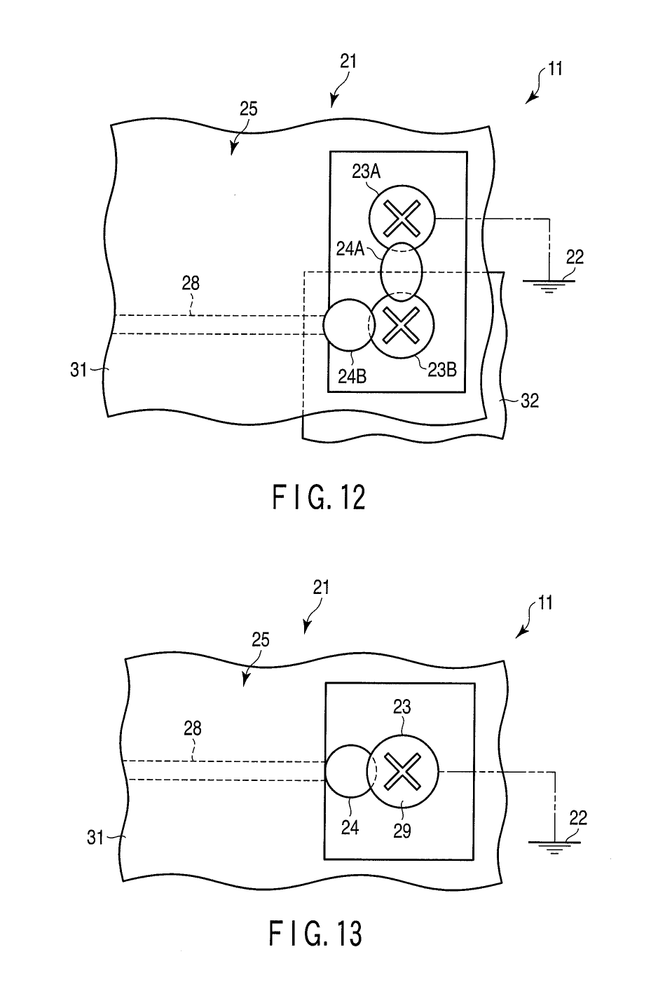

Referring then to FIG. 12, an electronic device according to a sixth embodiment will be described. A hard disk drive 11 as an example of the electronic device of the sixth embodiment is similar to that of the first embodiment except for the number of the conductive adhesive members 24, and the number of the fixing member 23. In the sixth embodiment, elements similar to those of the first embodiment are denoted by corresponding reference numbers, and will not be described. A description will be mainly given of different elements. The hard disk drive 11 of the sixth embodiment has the same appearance as that of FIG. 1.

The hard disk drive 11 of the sixth embodiment comprises a metal housing 12, a printed circuit board 13 fixed to an outer surface of the housing 12, a magnetic disk 14 housed in the housing 12, a rod-shaped carriage 15 rotatably attached to the housing 12, a recording/reproducing head 16 attached to the tip of the carriage 15, a flexible printed wiring board 21 housed in the housing 12, and an insulating fixing section 32 contained in the case 12B of the housing 12. The carriage 15 is formed of a metal and serves as a conductive member.

The hard disk drive 11 of the sixth embodiment further comprises first fixing members 23A fixing the flexible printed wiring board 21 to the support member 22, second fixing members 23B fixing the flexible printed wiring board 21 to the fixing section 32, first conductive adhesive members 24A each electrically connecting the corresponding first and second fixing members 23A and 23B, second conductive adhesive members 24B each electrically connecting the corresponding metal foil member 28 and the corresponding second fixing member 23B. Each second fixing member 23B is located adjacent to the tip of the corresponding metal foil member 28 and to the corresponding first fixing member 23A. Each second fixing member 24B covers the tip of the corresponding metal foil member 28.

The metal foil members 28, except for one of them, are provided in the main body 25 of the flexible printed wiring board 21, and the one metal foil member 28 is provided in the end portion 26 of the flexible printed wiring board 21 although it is not shown.

The fixing members 23A and 23B provided in the main body 25 of the flexible printed wiring board 21 are connected to a support member 22 as a conductive member. The metal foil members 28 in the main body 25 are grounded to the support member 22 via the first and second fixing members 23A and 23B, and the first and second conductive adhesive members 24A and 24B. Similarly, the fixing members 23A and 23B provided in the end portion 26 of the flexible printed wiring board 21 are connected to the carriage 15 as another conductive member. The metal foil member 28 in the end portion 26 is grounded to the carriage 15 via the first and second fixing members 23A and 23B, and the first and second conductive adhesive members 24A and 24B.

In the sixth embodiment, even when there is a distance between the metal foil member 28 and the first fixing member 23A, the metal foil member 28 can be grounded to the second case 12B since the second fixing member 23B is interposed between the metal foil member 28 and the first fixing member 23A.

In the sixth embodiment, the hard disk drive 11 comprises: the conductive members; the printed wiring board including the insulating base member 27 and the metal foil members 28 provided on one surface of the base member 27; the first fixing members 23A fixing the printed wiring board to the conductive members; the fixing section 32 fixed to the printed wiring board; the second fixing members 23B each located adjacent to the corresponding metal foil member 28 and first fixing member 23A and fixing the printed wiring board to the fixing section 32; the first conductive adhesive members 24A electrically connecting the first fixing members 23A to the second fixing members 23B; and the second conductive adhesive members 24B covering the surface potions of the metal foil members 28 and electrically connecting the metal foil members 28 to the second fixing members 23B.

In this structure, even when there is a distance between the metal foil member 28 and the first fixing member 23A, the metal foil member 28 can be grounded to the first fixing member 23A since the second fixing member 23B, the first conductive adhesive members 24A, and the second conductive adhesive members 24B are interposed between the metal foil member 28 and the first fixing member 23A. This makes it unnecessary to, for example, change the position of the metal foil member 28 on the printed wiring board, or to change the position of the fixing member 23A or 23B. As a result, reliable grounding of the metal foil member 28 to the conductive members can be realized at low cost.

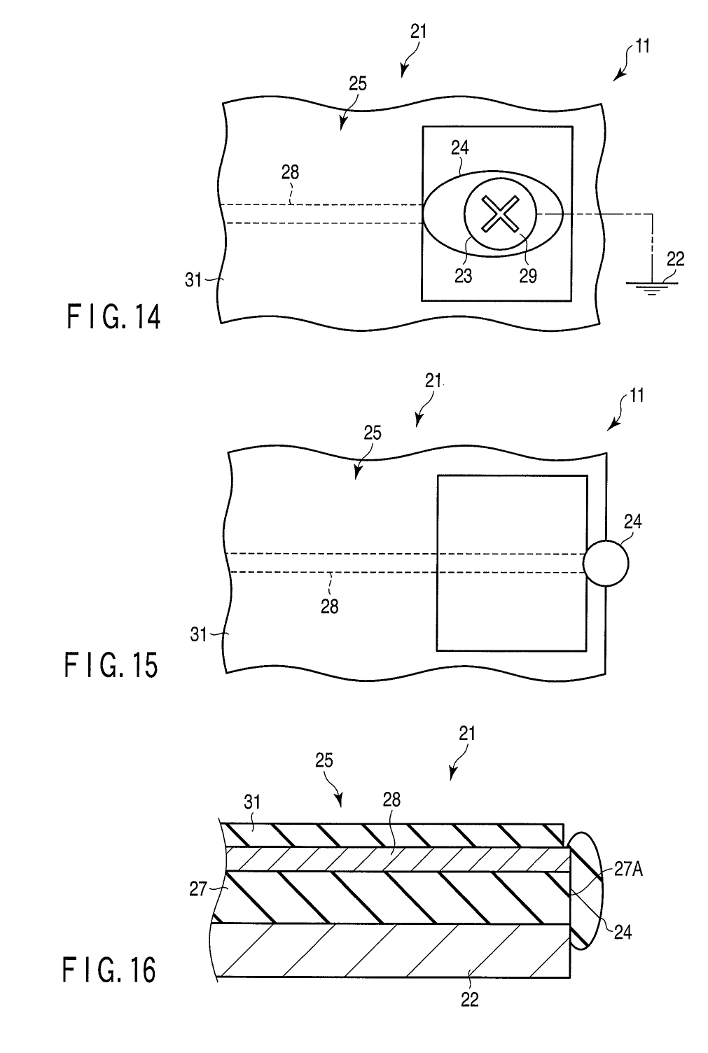

Referring to FIGS. 13 and 14, an electronic device according to a seventh embodiment will be described. A hard disk drive 11 as an example of the electronic device of the seventh embodiment is similar to that of the first embodiment except for the positional relationship between each fixing member 23 and the corresponding conductive adhesive member 24. In the seventh embodiment, elements similar to those of the first embodiment are denoted by corresponding reference numbers, and will not be described. A description will be mainly given of different elements. The hard disk drive 11 of the seventh embodiment has the same appearance as that of FIG. 1.

As can be understood from FIG. 13, metal foil members 28 (only one of which is shown) are provided in the main body 25 of a flexible printed wiring board 21. Another metal foil member 28 is provided in the end portion 26 of the flexible printed wiring board 21 although it is not shown.

Each conductive adhesive member 24 covers the tip of the corresponding metal foil member 28 to electrically connect the metal foil member to the corresponding fixing member 23. After coating the conductive adhesive members 24, the fixing members 23 are fixed. A part of the exposed portion 29 of each fixing member 23 is provided on the upper surface of the corresponding conductive adhesive members 24, i.e., the corresponding conductive adhesive members 24 is provided on the lower surface of the exposed portion 29. Namely, each conductive adhesive member 24 is provided between the exposed portion 29 of the corresponding fixing member 23 and the flexible printed wiring board 21.

The fixing members 23 in the main body 25 of the flexible printed wiring board 21 are connected to a support member 22 as a conductive member. The metal foil members 28 in the main body 25 are grounded to the support member 22 via the corresponding conductive adhesive members 24 and the corresponding fixing members 23. Similarly, the fixing member 23 in the end portion 26 of the flexible printed wiring board 21 is connected to a carriage 15 as another conductive member. The metal foil member 28 in the end portion 26 is grounded to the carriage 15 via the corresponding fixing member 23 and the corresponding conductive adhesive member 24.

Since in the seventh embodiment, each conductive adhesive member 24 is interposed between the exposed portion 29 of the corresponding fixing member 23 and the flexible printed wiring board 21, it is not easily detached from the flexible printed wiring board 21. By virtue of this structure, an electronic device, in which the physical strength of the portions around the conductive adhesive members 24 is enhanced, can be provided. Further, since the fixing members 23 are often formed of, for example, stainless steel, no dust will be raised by the fixing members 23, and it is not necessary to cover the fixing members 23 with the conductive adhesive members 24.

FIG. 14 shows a modification of the seventh embodiment. In this modification, the adhesion area of each conductive adhesive member 24 is greater area than in the case of FIG. 13. Further, since the entire exposed portion 29 of each fixing member 23 is provided on the upper surface of the corresponding conductive adhesive member 24, the possibility of peeling off of the conductive adhesive member 24 is further reduced because of its increased adhesion area. Thus, the physical strength of the modification is stronger than the seventh embodiment of FIG. 13.

Referring to FIGS. 15 and 16, an electronic according to an eighth embodiment will be described. A hard disk drive 11 as an example of the electronic device of the eighth embodiment is similar to that of the first embodiment except that the former employs no fixing members 23 and differs from the latter in the coating positions of the conductive adhesive members 24. In the eighth embodiment, elements similar to those of the first embodiment are denoted by corresponding reference numbers, and will not be described. A description will be mainly given of different elements. The hard disk drive 11 of the eighth embodiment has the same appearance as that of FIG. 1.

The hard disk drive 11 of the eighth embodiment comprises a metal housing 12, a printed circuit board 13 fixed to an outer surface of the housing 12, a magnetic disk 14 housed in the housing 12, a rod-shaped carriage 15 rotatably attached to the housing 12, a recording/reproducing head 16 attached to the tip of the carriage 15, a flexible printed circuit board 21 housed in the housing 12, and a fixing section 32 attached to the second case 12B of the housing 12. The housing 12 is a conductive member, and includes an upper (first) case 12A and a lower (second) case 12B. The carriage 15 is formed of a metal, and is another conductive member.

The flexible printed wiring board 21 comprises a base member 27 formed of, for example, polyimide, metal foil members 28 (copper foil members) provided on one surface of the base member 27, and cover layers 31 formed of, for example, polyimide and covering the metal foil members 28.

As shown in FIGS. 15 and 16, the metal foil members 28, except for one of them, are provided in the main body 25 of the flexible printed wiring board 21, and the one metal foil member 28 is provided in the end portion 26 of the flexible printed wiring board 21 although it is not shown.

The hard disk drive 11 of the eighth embodiment further comprises conductive adhesive members 24 that cover the tips of the metal foil members 28. The conductive adhesive members 24 are provided on an end face 27A of the base member 27 perpendicular to the abovementioned one surface of the base member 27. As shown in FIG. 16, each conductive adhesive member 24 provided in the main body 25 of the flexible printed wiring board 21 fixes the main body 25 to a support member 22. Another conductive adhesive member 24 is provided in the end portion 26 of the flexible printed wiring board 21, although it is not shown. This conductive adhesive member 24 fixes the end portion 26 of the flexible printed wiring board 21 to the carriage 15.

The metal foil members 28 in the main body 25 are grounded to the support member 22 as a conductive member via the corresponding conductive adhesive members 24. The metal foil member 28 in the end portion 26 is grounded to the carriage 15 as another conductive member via the corresponding conductive adhesive member 24.

In the eighth embodiment, the hard disk drive 11 comprises: the conductive members; the printed wiring board including the insulating base member 27 and the metal foil members 28 provided on one surface of the base member 27; the conductive adhesive members 24 that are provided on the end face 27A, perpendicular to the one surface of the base member 27, for fixing the printed wiring board to the conductive members and electrically connecting the metal foil members 28 to the conductive members.

This structure enables the printed wiring board to be physically connected to the conductive members without any fixing members 23, and also enables the metal foil members 28 to be grounded to the conductive members. Thus, both physical connection and grounding of the flexible printed wiring board 21 to the conductive members can be realized without, for example, any fixing members. Although in the eighth embodiment, the conductive adhesive members 24 are provided on the end face 27A of the base member 27 to ground the metal foil members 28 to the conductive members, the use of the conductive adhesive members 24 is not limited to this, but they may be used as part of an electric circuit.

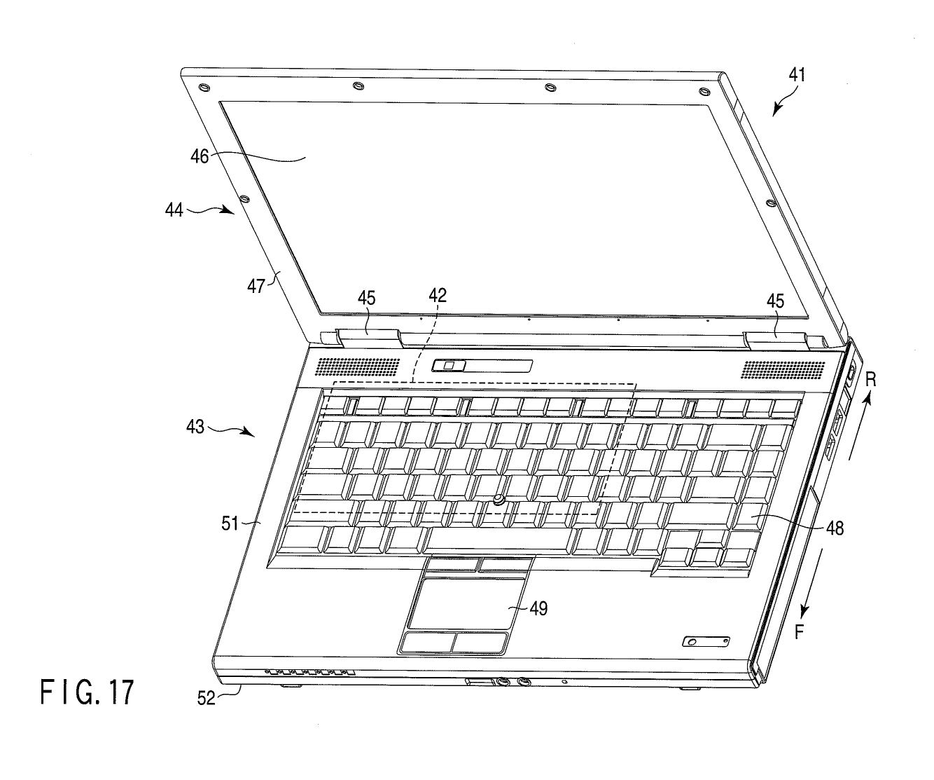

Referring then to FIGS. 17 to 19, an electronic device according to a ninth embodiment will be described. A portable computer 41 as an example of the electronic device of the ninth embodiment is similar to the first embodiment except that the former employs a rigid printed wiring board 42 in place of the flexible printed wiring board, and has an appearance different from the first embodiment. In the ninth embodiment, elements similar to those of the first embodiment are denoted by corresponding reference numbers, and will not be described. A description will be mainly given of different elements.

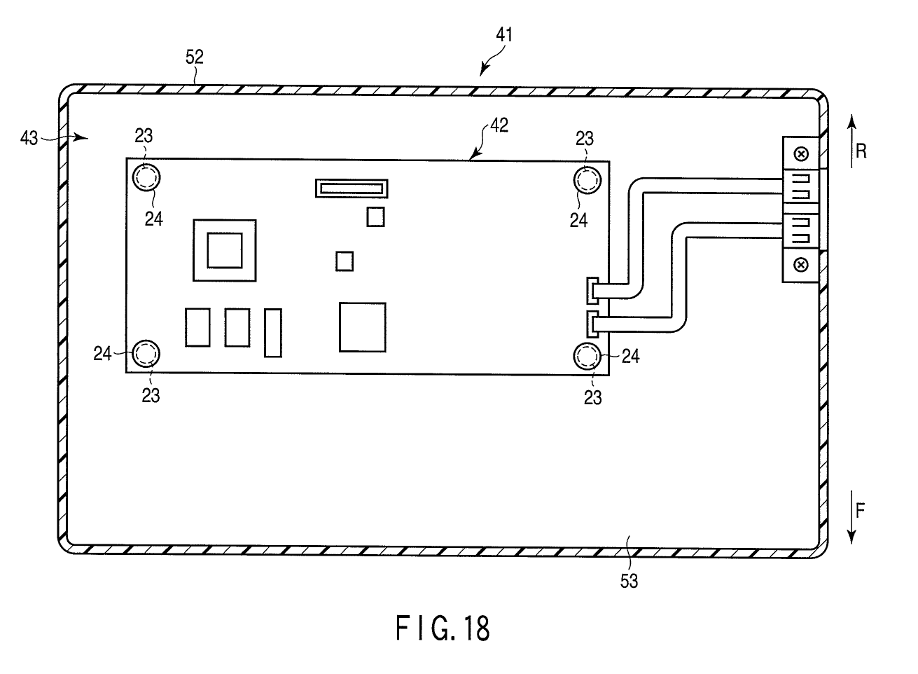

In FIGS. 17 and 18, the near side to the user (that is, user side) is defined as front F, the far side from the user is rear R, the left-hand side of the user is left, the right-hand side of the user is right, the upper side from the user's position is up and the lower side from the user's position is down.

As shown in FIG. 17, the portable computer 41 as an example of the electronic device comprises a main unit 43, a display unit 44, and hinges 45 provided between the main unit 43 and the display unit 44. The hinges 45 support the display unit 44 so that the display unit can rotate.

The display unit 44 comprises a liquid crystal display 46, and a display cabinet 47 enclosing the liquid crystal display 46.

As can be seen from FIGS. 17 to 19, the main unit 43 comprises a housing 12 (body cabinet), a keyboard 48 and a touch pad 49 on the housing 12, and a rigid printed wiring bard 42 housed in the housing 12 and having a plurality of circuit components mounted thereon.

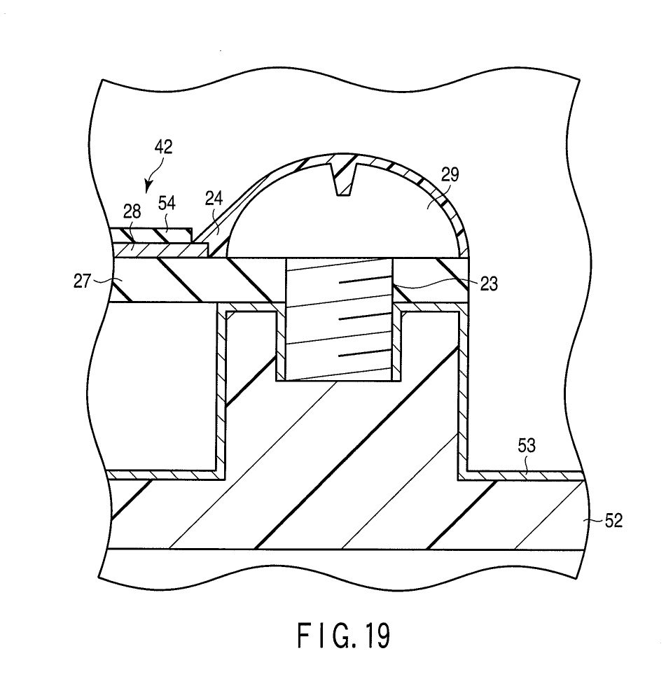

The housing 12 has an upper case 51 and a lower case 52. The lower case 52 includes a shield layer 53 provided on an inner surface thereof and formed of a metal thin film. The lower case 52 is a conductive member. The upper case 51 includes a similar shield layer 53. As can be understood from FIG. 19, the main unit 43 further comprises fixing members 23 for fixing the printed wiring bard 42 to the lower case 52, and conductive adhesive members 24 each covering the entire exposed portion 29 of the corresponding fixing member 23.

The printed wiring board 42 comprises an insulating base member 27, metal foil members 28 (copper foil members) provided on one surface of the base member 27, and layers 54 formed of, for example, solder resist and covering the metal foil members 28. The conductive adhesive members 24 cover the tips of the metal foil members 28 and electrically connect the metal foil members 28 to the fixing members 23. The metal foil members 28 are grounded to the lower case 52 as a conductive member via the conductive adhesive members 24 and the fixing members 23.

As described above, in the ninth embodiment, the portable computer 41 comprises the conductive members; the printed wiring board 42 including the insulating base member 27 and the metal foil members 28 provided on one surface of the base member 27; the fixing members 23 fixing the printed circuit board 42 to the conductive members; and the conductive adhesive members 24 covering surface potions of the metal foil members 28 and electrically connecting the metal foil members 28 to the fixing members 23.

Since in this structure, the surfaces of the metal foil members 28 are coated with the conductive adhesive members 24, oxide films that may become dust are prevented from being formed on the metal foil members 28. Further, since the conductive adhesive members 24 electrically connect the metal foil members 28 to the fixing members 23, the metal foil member 28 can be reliably grounded to the conductive members. Further, since no gold plating is employed, both the manufacturing cost of the device and the environmental load can be reduced.

Further, in the ninth embodiment, since the entire exposed portions 29 of the fixing members 23 are covered, the connection strength of the fixing members 23 and their peripheral portions is enhanced, and the fixing members 23 are prevented from being loosened. Although in the ninth embodiment, the structure of the first embodiment is applied to the portable computer 41, the portable computer 41 is not limited to this. The structures according to the second to eighth embodiments shown in FIGS. 7 to 16 are also applicable to the structure for fixing the printed wiring board 42 to the lower case 52 of the housing 12 in the portable computer 41.

The electronic devices are not limited to the hard disk drive 11 and the portable computer 41 described in the above embodiments, but may be other types of electronic devices such as a mobile phone.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An electronic device comprising:
a conductive housing;
a printed wiring board comprising an insulating base, and at least one metal foil portion on one surface of the base;
an attaching portion configured to attach the printed wiring board to the conductive housing; and
at least one conductive adhesive portion covering a surface of the at least one metal foil portion and configured to electrically connect the at least one metal foil portion to the attaching portion.

2. The electronic device of claim 1, wherein the attaching portion comprises a bulge out of the printed wiring board, at least a portion of the bulge is covered with the at least one conductive adhesive portion.

3. The electronic device of claim 2, wherein the at least one conductive adhesive portion comprises a plurality of conductive adhesive portions, the plurality of conductive adhesive portions being around the attaching portion.

4. The electronic device of claim 3, wherein the at least one metal foil portion comprises a plurality of metal foil portions, the plurality of metal foil portions being around the attaching portion and corresponding to the plurality of conductive adhesive portions.

5. The electronic device of claim 1, wherein the conductive adhesive portion is located between the bulge of the attaching portion and the printed wiring board.

6. An electronic device comprising:
a printed wiring board comprising an insulating base, and a first metal foil portion and a second metal foil portion on one surface of the base;
an area to which the printed wiring board is attached;
an attaching portion configured to attach the printed wiring board to the area;
a first conductive adhesive portion covering a surface of the first metal foil portion and configured to electrically connect the first metal foil portion to the attaching portion; and
a second conductive adhesive portion covering a surface of the second metal foil portion and configured to electrically connect the second metal foil portion to the attaching portion.

7. The electronic device of claim 6, wherein the attaching portion comprises a bulge out of the printed wiring board, at least portions of the bulge are covered with and the first and second conductive adhesive portions.

8. An electronic device comprising:
a conductive housing;
a printed wiring board comprising an insulating base, and a metal foil portion on one surface of the base;
a first attaching portion configured to attach the printed wiring board to the conductive housing;
an area to which the printed wiring board is attached;
a second attaching portion next to the metal foil portion and the first attaching portion configured to attach the printed wiring board to the area;
a first conductive adhesive portion configured to electrically connect the first attaching portion to the second attaching portion; and
a second conductive adhesive portion covering a surface of the metal foil portion and configured to electrically connect the metal foil portion to the second attaching portion.
